(19) United States
(12) Patent Application Publication
(10) Pub. No.: US 2006/0215459 A1
(43) Pub. Date: Sep. 28, 2006

(54) Active and Passive Programming/Erasing Time and Verifiable Reading for Memory System

(75) Inventors: PingFu Hsieh, Tainan (TW); KuoCheng Weng, Kaohsiung (TW); LiangHung Wang, Tainan (TW)

Correspondence Address: BEEDAR TECHNOLOGY INC., R206, #12, NAN-KE 2ND ROAD,, TAINAN SCIENCE-BASED INDUSTRIAL PARK, TAINAN, TW

(73) Assignee: BEEDAR TECHNOLOGY INC., Tainan (TW)

(21) Appl. No.: 10/907,225

(22) Filed: Mar. 24, 2005

(51) Int. Cl. G11C 11/34; G11C 16/04

(52) U.S. Cl. 365/185.29

(57) ABSTRACT

A new specific memory control unit design to apply program and erase function wherein use the new methodology of memory configured logic to manipulate timing parameter.

### FIELD OF THE INVENTION

The invention addresses to manipulate the time of program/erase operation in memory field. There may be either active or passive methodology. The active methodology of the program/erase time can be adjusted by control unit. On the other hand, the passive methodology performs the program/erase operation by setting a fixed configuration of time manually. For data integrity, check sum procedures are proposed in reading verification.

### BACKGROUND OF THE INVENTION

The conventional program/erase time is defined by experimental results of the specific memory cell. There is no way to adjust time quickly and conveniently. Thus, to re-produce new product, the only way is going to tape-out and change new mask. Goals of invention are to overcome the inconvenient design and provide the new control unit to manipulate program/erase time of memory without spending more investment. Eventually, it will extend reliability of memory cell and improve the precision in reading and writing.

### SUMMARY OF THE INVENTION

The invention overcomes the unchangeable program/erase time. Further, it even can be divided by passive and active program/erase time configurations. The difference between passive and active procedures of program/erase time is that active can modify or re-write the configuration into memory, but the passive procedure can not.

A feature of the passive program/erase time of the invention includes multi-combinational methods of iterative time and cycle to adjust proper program/erase time. However, the configuration is not modified at all and the verified iteration may occur again if the program/erase time is not adequate to memory cell.

The active program/erase time flow not only verifies and corrects proper program/erase time but also writes the proper program/erase time configuration into memory. This invention may adjust proper program/erase time simultaneously to be adapted in current characteristics of memory cell.

Above features of the invention are in write mode. In the read mode, the verified method is also employed in data path between memory and control unit. The feature of invention is the data wherein read out from memory is carrying along with check sum. The check methods are available to select and depend on different types of data stream.

### DESCRIPTION OF THE FIGURES

FIG. 1 depicts the block diagram of control unit and memory.

FIG. 2 depicts a configured block of the memory map.

TABLE 1 depicts to set up the program duration time.

TABLE 2 depicts to set up the check sum procedure.

FIG. 3 depicts the check sum procedure flow in read mode.

FIG. 4 depicts a flow chart of the passive program/erase function in write mode.

FIG. 5 depicts a flow chart of the active program/erase function in write mode.

### DETAILED DESCRIPTION OF THE FIGURES

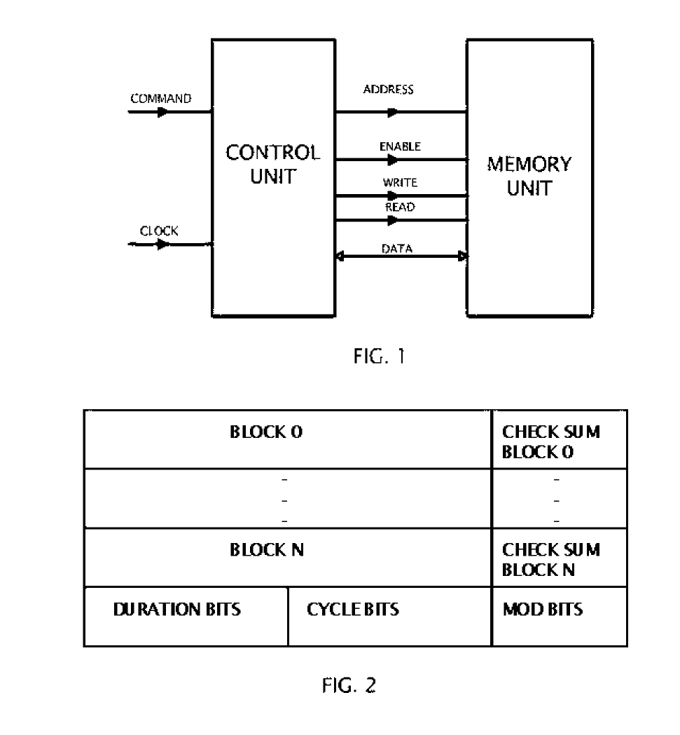

FIG. 1 depicts the function block diagram. CLOCK is input signal of the system clock. ENABLE is used to enable memory. If COMMAND signal is ready for writing, the control unit outputs ADDRESS, WRITE and DATA to memory. If COMMAND signal is ready for reading, it asserts ADDRESS and READ to memory then gets DATA form memory.

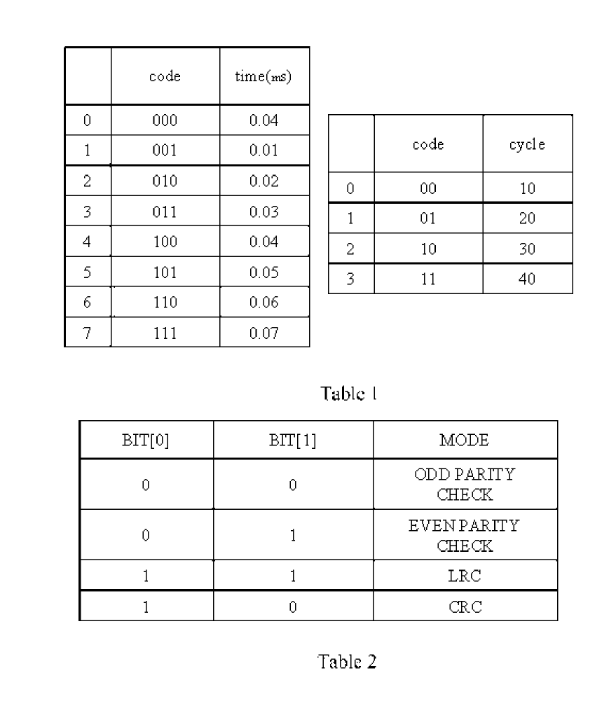

FIG. 2 depicts a configuration block on memory. It contains programming, erasing duration bits and check sum mode.

Table 1 depicts to set up the programming and erasing duration time. The index is stored in the configuration block. The setting programming and erasing time is got from the look up table.

Table 2 depicts to set up the mode of check sum procedure.

The check sum procedures have four modes as odd or even parity check, longitudinal redundancy check (LRC), and cyclic redundancy check (CRC). The BIT [0:1 ] in check sum bits are designed to alter one of the check sum procedures. When the BIT [0:1] is equal to 00, the status with odd parity check is asserted. When the BIT [0:1] is equal to 01, the status with even parity check is asserted. When the BIT [0:1 ] is equal to 00, 01, a parity bit is in incorporated into each bit, byte, or block in parity check mode. When the BIT [0:1 ] is equal to 11, each LRC check is generated by the XOR gated with recursion in each byte in LRC mode. The LRC algorithm is that the transmitted value extended formatted bytes is appended to a LRC byte and a data block. When the BIT [0:1] is equal to 10, enable a CRC procedure. The CRC algorithm is calculated by the dividing way of the polynomial in the logic unit. The CRC polynomial value of the memory data includes the appended CRC byte.

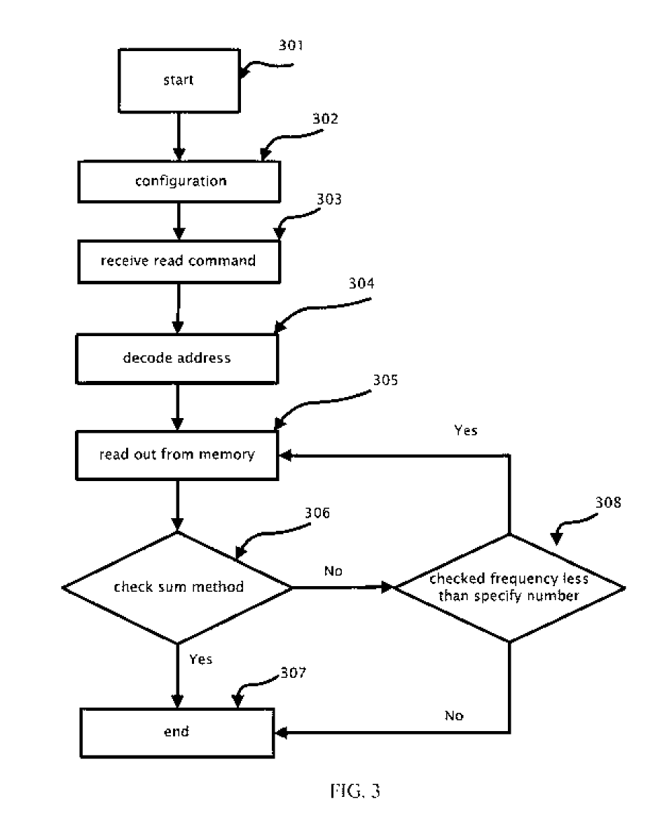

FIG. 3 depicts the check sum procedure flow in read mode.

First, Control unit reads check sum mode of configuration from memory 302 and set its mode. When it receives read command 303 then decodes the address 304. Control unit asserts read signal to memory and read back the data of selected address 305. The data will be verified by predetermined check sum method 306. The variable check sum methods include odd or even parity check, longitudinal redundancy check (LRC), and cyclic redundancy check (CRC). Table 2 illustrates these check sum methods and represented code. Moreover, the read command contains the value of iterations. For instance, the iteration was set to be 5 if the check sum goes wrong. The verified iteration runs five times to gain integrity result. There are two situations that check sum flow goes to the end 307. Thus, at this moment, the data is ready to send out. One is the check sum is correct, the other is the iterations rate meets the maximum predetermined value.

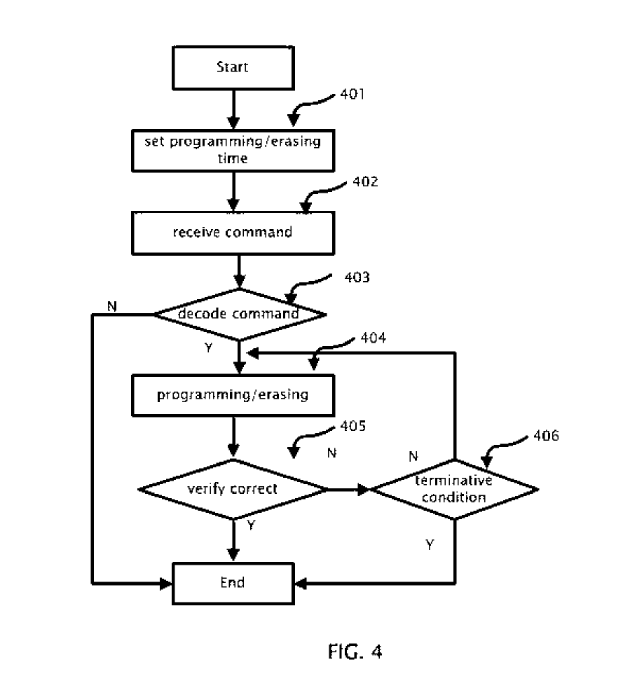

FIG. 4 depicts a flow chart of the passive program/erase function.

First, the control unit reads a time index of programming/erasing configuration from memory. According to a look up table, it gets the setting programming/erasing time 401. For example, the configuration index is 000001. According to Table 1, its programming/erasing time is 0.01 ms.

When control unit receives an available write command 402 then enter write procedure. The programming/erasing address is decoded from the command 403. If the command is correct then start to program/erase, otherwise breaks write procedure.

Control unit sustains to assert programming/erasing control signals and address to memory until it is on the setting programming/erasing time 404. The written data is read back and checked whether it is correct or not 405. If the verification result is correct then write procedure completes. Otherwise, the write procedure continues to program/erase until it is on terminative condition 406. Terminative condition is a setting maximum programming/erasing time or cycles. When the total number of cycles meet maximum one then breaks write procedure. The successive programming/erasing is decided by terminative condition.

The terminative condition is combined time and cycle arrangements. The terminative condition includes five bits configuration, composed of three bits time code, and two bits cycle code in Table 1. The time code of 000 means the programming/erasing time of 0.01 ms. Each cycle is continued in the same way. The write procedure continues until data is correct or total programming/erasing meets maximum cycle. The code of 001 represents the time of 0.02 ms, the code of 010 does the time of 0.03 ms, and so on. The cycle code of 00 represents 10 cycles, the code of 01 represents 20 cycles, and so on. The write procedure continues until data is correct or total programming/erasing cycle is on maximum cycle. For example, the time code of 010 and the cycle code of 10 illustrate cyclic programming/erasing time of 0.03 ms until the cycles meet 30 times.

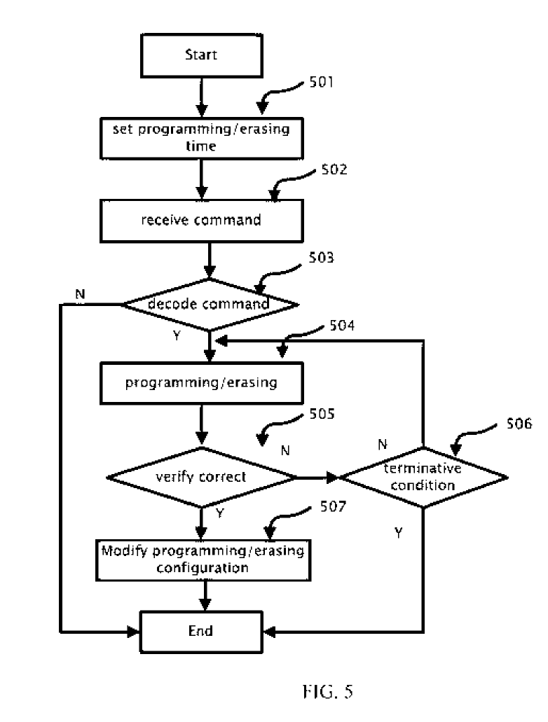

FIG. 5 depicts a flow chart of the active program/erase function. The main different between passive and active programming/erasing procedures is terminal conditions. The control unit sums up the total times 507 during this programming/erasing. The total time is stored in configuration in memory, and then next write procedure uses new programming/erasing time. We could obtain the high performance and extend the memory cell lifetime.

What is claimed is:

1. An arrangement of erase/program time control methodology, comprising:
a control unit operable to transmit/receive data, run algorithm, and manipulate data flow;
a memory structure operable to store information wherein includes program/erase and read function;
a plurality of procedure signals operable to operate functions;
a plurality of procedure signals operable to operate functions.

2. An arrangement of erase/program time control methodology of claim 1, further comprising the passive steps of:
a verified unit wherein verify the reserved data and programmed/erased data;
a terminative condition unit wherein execute program time operations;
a configuration wherein stored combinational program time operations in the memory unit.

3. An arrangement of erase/program time control methodology of claim 1, further comprising the active steps of:
a verified unit wherein verify the reserved data and programmed/erased data;
a terminative condition unit wherein execute program time operations;
a configuration wherein stored combinational program time operations in the memory unit;
a modified unit wherein be able to rewrite the program time configurations in the memory.

4. A verified methodology in the read mode, comprising the steps of:
a check sum unit wherein contains variable check sum algorithms;
a configuration wherein stored variable check sum commands in the memory unit;
a counter wherein counts the iterations of check sum.
